(19) United States
(12) Patent Application Publication
(10) Pub. No.: US 2025/0364445 A1
(43) Pub. Date: Nov. 27, 2025

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: YI-FONG LAI, CHANGHUA COUNTY (TW); CHUNG-CHUAN TSENG, HSINCHU CITY (TW); PO-YU CHEN, HSINCHU CITY (TW); LI-WEN HO, HSINCHU CITY (TW); YU-CHEN DENG, TAOYUAN CITY (TW)

(21) Appl. No.: 18/674,959

(22) Filed: May 27, 2024

(51) Int. Cl. H01L 23/58; H01L 21/78

(52) U.S. Cl. CPC H01L 23/585; H01L 21/78

(57) ABSTRACT

A method for forming semiconductor structures includes following operations. A substrate having a plurality of die regions is received. The substrate has a first side and a second side opposite to the first side. First trenches and second trenches are formed to separate the die regions. The first trenches extend in a first direction, and the second trenches extend in a second direction different from the first direction. The first trenches and the second trenches intersect to form intersections. A width of the intersection is less than or equal to each of a width of the first trench and a width of the second trench. A protection layer is formed over a bottom and sidewalls of each first trench, each second trench and each intersection. An isolation separating the plurality of die regions from each other is formed in the first trenches, the second trenches and the intersections.

### BACKGROUND

Electronic equipment that uses semiconductor devices is essential for many modern applications. With the advancement of electronic technology, semiconductor dies are becoming smaller in size and based on greater amounts of integrated circuitry. In addition, greater numbers of functions need to be integrated into the semiconductor dies. As a result, the packaging of the semiconductor dies is becoming more and more challenging.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a layout view of a plurality of die regions in an array in accordance with some embodiments of the present disclosure.

FIGS. 2A to 2D are partially enlarged views in a frame of FIG. 1 in a step subsequent to that shown in FIG. 1 in accordance with various embodiments of the present disclosure.

FIG. 3A is a schematic cross-sectional view taken along line I-I′ of FIGS. 2A to 2D, and FIG. 3B is a schematic cross-sectional view taken along line II-II′ of FIGS. 2A to 2D in accordance with some embodiments of the present disclosure.

FIGS. 4A and 4B are schematic cross-sectional views in a step subsequent to that shown in FIGS. 3A and 3B in accordance with some embodiments of the present disclosure.

FIGS. 5A and 5B are schematic cross-sectional views in a step subsequent to that shown in FIGS. 4A and 4B in accordance with some embodiments of the present disclosure.

FIGS. 6A and 6B are schematic cross-sectional views in a step subsequent to that shown in FIGS. 5A and 5B in accordance with some embodiments of the present disclosure, wherein FIG. 6C is a partially enlarged view, FIG. 6A further is a schematic cross-sectional view taken along line I-I′ of FIG. 6C, and FIG. 6B further is a schematic cross-sectional view taken along line II-II′ of FIG. 6C in accordance with some embodiments of the present disclosure.

FIGS. 7 to 13 are schematic cross-sectional views of the semiconductor structure in steps subsequent to those shown in FIGS. 6A to 6C in accordance with some embodiments of the present disclosure.

FIG. 14 is a flow diagram of a method for forming semiconductor structures in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, a semiconductor structure is disclosed. The semiconductor structure includes at least a protrusion disposed over a corner formed by edges of the semiconductor structure as seen as in a plan view. Such protrusion helps to mitigate a defect issue arising in manufacturing operations by improving trench/gap-filling result.

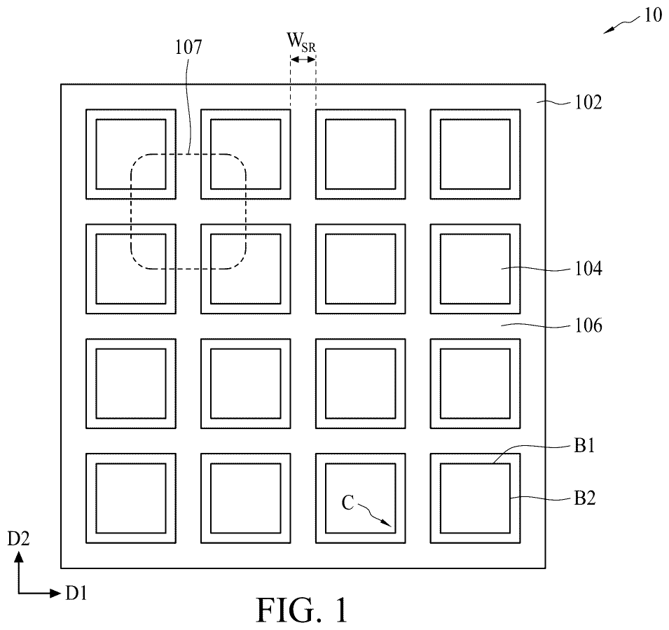

Referring to FIG. 1, FIG. 1 is a layout view of a plurality of die regions in accordance with various embodiments of the present disclosure. In some embodiments, a substrate, such as a semiconductor substrate 102, is provided or received. The semiconductor substrate 102 may be a wafer substrate. In some embodiments, the semiconductor substrate 102 includes a semiconductor material such as silicon (Si), germanium (Ge), diamond, or the like. In other embodiments, the semiconductor substrate 102 can include compound materials such as SiGe, silicon carbide (SiC), gallium arsenic (GaAs), indium arsenide (InAs), indium phosphide (InP), silicon germanium carbide SiGeC, gallium indium phosphide (GaInP), a combination of these, or the like. Additionally, the semiconductor substrate 102 can be a silicon-on-insulator (SOI) substrate. However, embodiments of the disclosure are not limited thereto.

In some embodiments, a plurality of package component regions (not shown) may be defined over the semiconductor substrate 102. In some embodiments, each of the package component regions has a quadrilateral, rectangular or square shape as seen in a plan view. In some embodiments, the package component regions are arranged to form a column-and-row array and separated from each other by scribe lines. In some embodiments, a width of the scribe line may be between approximately 50 micrometers and approximately 100 micrometers, but the disclosure is not limited thereto.

In some embodiments, each of the package component regions further includes a plurality of die regions 104 or a plurality of micro-die regions 104. In other embodiments, in an absence of the package component regions, a plurality of die regions 104 or a plurality of micro die regions 104 can be defined in the semiconductor substrate 102. In some embodiments, each of the die regions 104 has quadrilateral, rectangular or square shape as seen in the plan view. As shown in FIG. 1, the die regions 104 are arranged in a first direction D1 and a second direction D2 that is different from the first direction D1. In some embodiments, the first direction D1 and the second direction D2 are perpendicular to each other. Further, the first direction D1 and the second direction D2 form a plane that is parallel to a surface of the semiconductor substrate 102. Accordingly, the die regions 104 are arranged to form a column-and-row array and separated from each other by a separation region 106. In some embodiments, the separation region 106 may be referred to as a micro-scribe line, but the disclosure is not limited thereto. In such embodiments, a width W_{SR} of the separation region 106 is much less than the width of the scribe line. In some embodiments, the width W_{SR} of the separation region 106 is between approximately 1 micrometer and approximately 2 micrometers, but the disclosure is not limited thereto.

Various active elements (not shown) are formed in and/or over the semiconductor substrate 102, in accordance with some embodiments. Further, the active elements are formed in each of the die regions 104. Examples of the various active elements include transistors, diodes, other suitable elements, or a combination thereof. The transistors may be metal-oxide-semiconductor field-effect transistors (MOSFET), complementary metal oxide semiconductor (CMOS) transistors, bipolar junction transistors (BJT), high-voltage transistors, high-frequency transistors, p-channel and/or n-channel field-effect transistors (PFETs/NFETs), diodes, photodiodes, etc. In some embodiments, various passive elements (not shown) may also be formed in and/or over the semiconductor substrate 102. In such embodiments, the passive elements may be formed in each of the die regions 104. Examples of the various passive elements include capacitors, inductors, resistors, other suitable passive elements, or a combination thereof.

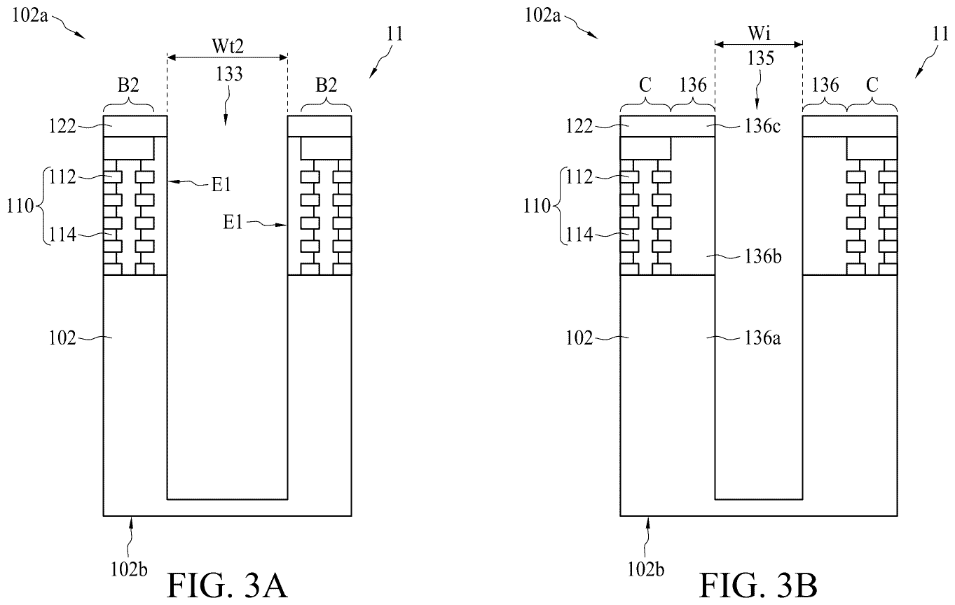

The abovementioned active and/or passive elements may be formed over a first side 102a (shown in FIGS. 3A and 3B) of the semiconductor substrate 102, which may be referred to as an active surface. The active and/or passive elements may be formed in and/or over the semiconductor substrate 102 using front-end semiconductor fabrication processes, which may be referred to as front end of line (FEOL) processes. Subsequently, an interconnect structure 110 (shown in FIGS. 3A and 3B) may be formed over the semiconductor substrate 102 using back-end semiconductor fabrication processes, which may be referred to as back end of line (BEOL) processes. The BEOL interconnect structure 110 includes a metallization structure 112 disposed in a dielectric structure 114, both of which are shown in FIGS. 3A to 6B.

In some embodiments, the dielectric structure 114 may include a plurality of dielectric layers (not shown) formed over the first side 102a of the semiconductor substrate 102 in accordance with some embodiments. The dielectric layers cover the active and/or passive elements over the semiconductor substrate 102. The dielectric layers may be a multi-layer structure (not shown), which includes an interlayer dielectric (ILD) layer and one or more inter-metal dielectric (IMD) layers. Multiple conductive features are formed in the ILD layer and IMD layers to form the metallization structure 112, and the metallization structure 112 is electrically connected to active or passive elements in and/or over the semiconductor substrate 102. Examples of the conductive features include conductive contacts, conductive lines and/or conductive vias.

In some embodiments, the dielectric layers of the dielectric structure 114 are made of silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable dielectric material, or a combination thereof. The material of the dielectric layers of the dielectric structures 114 is selected to minimize size, propagation delays, and crosstalk between nearby conductive features.

Please refer to FIG. 1. In accordance with some embodiments, the metallization structure 112 is separated from a boundary of each die region 104 in order to avoid damage from stress that is usually generated during die singulation. In accordance with such embodiments, an outermost portion of the metallization structure 112 is shown in FIG. 1. In some embodiments, the outermost portion of the metallization structure 112 may include a seal ring, but the disclosure is not limited thereto. In some embodiments, the outermost portion of the metallization structure 112 may be defined as having a first boundary B1 and a second boundary B2. The first boundary B1 extends in the first direction D1, and the second boundary B2 extends in the second direction D2. Further, the first boundary B1 and the second boundary B2 intersect to form a corner C, as shown in FIG. 1.

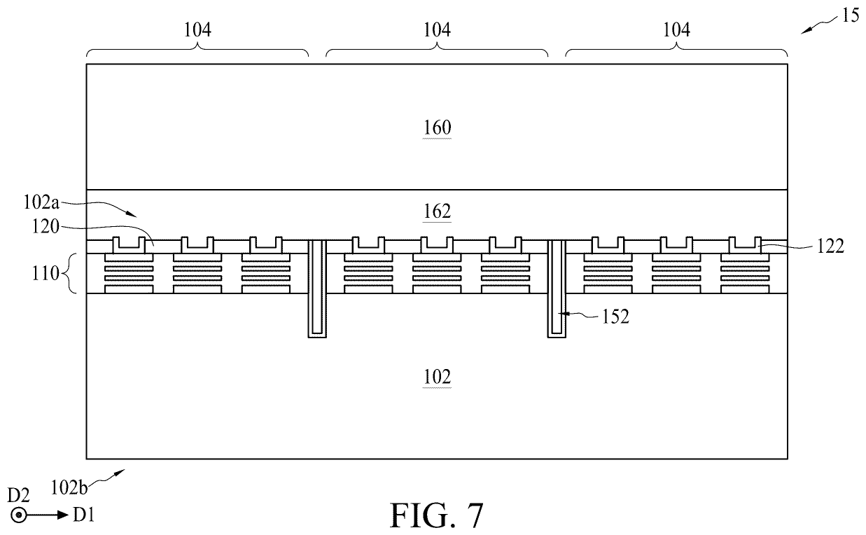

In some embodiments, conductive pads 120 (shown in FIG. 7) are formed over the BEOL interconnect structure 110. The conductive pads 120 are electrically connected to active or passive elements in and/or over the semiconductor substrate 102 through the metallization structure 112 of the BEOL interconnect structure 110. In some embodiments, the conductive pads 120 include aluminum (Al), copper (Cu), silver (Ag), gold (Au), nickel (Ni), tungsten (W), another suitable material, or a combination thereof.

In some embodiments, a passivation layer 122 (shown in FIGS. 3A to 6B) is formed over the BEOL interconnect structure 110 and the conductive pads 120. In some embodiments, the conductive pads 120 may be partially exposed through openings of the passivation layer 122. Further, although the passivation 122 is shown as a single layer in FIGS. 3A to 12B, the disclosure is not limited thereto. In some other embodiments, the passivation layer 122 is a multi-layer structure including sub-layers (not shown). In some embodiments, the passivation layer 122 is made of silicon oxide, silicon nitride, silicon oxynitride, polyimide (PI), polybenzoxazole (PBO), benzocyclobutene (BCB), another suitable dielectric material, or a combination thereof.

In some embodiments, connectors (not shown) may be formed over the passivation layer 122. The connectors are physically and electrically connected to the conductive pads 120 exposed through the openings of the passivation layer 122. The connectors may be conductive vias, conductive pillars or other suitable connectors. In some embodiments, the connectors include Cu, W, Ag, Au, another suitable material, or a combination thereof.

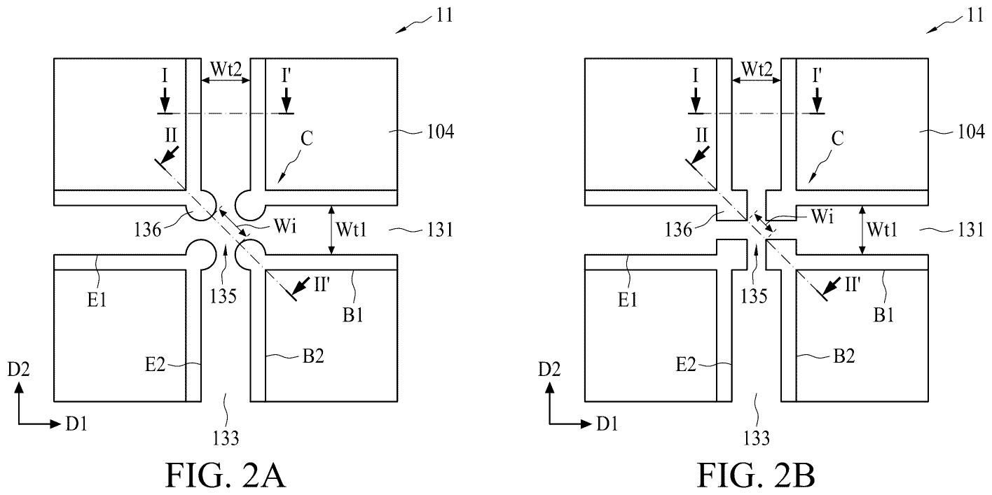

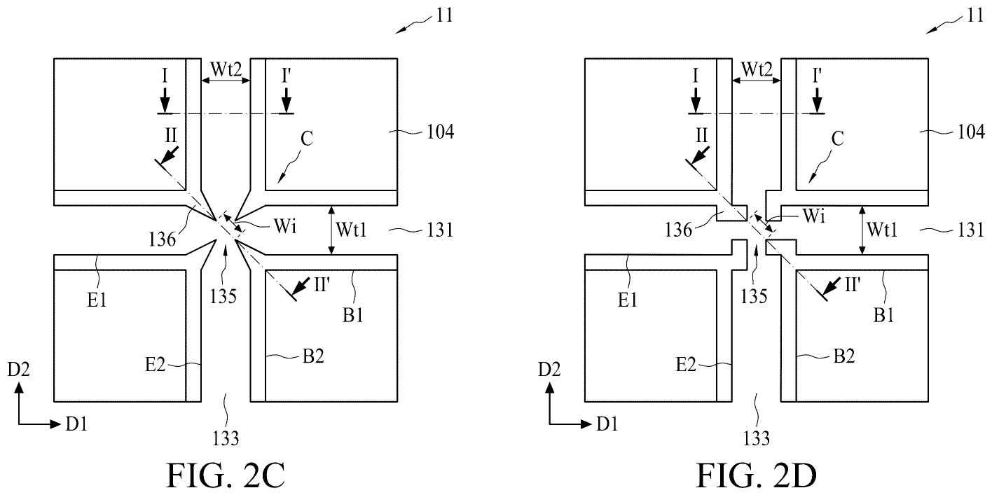

Please refer to FIGS. 2A to 3B, wherein FIGS. 2A to 2D are partially enlarged views of a frame 107 in FIG. 1, FIG. 3A is a cross-sectional view taken along line I-I′ of FIGS. 2A to 2D, and FIG. 3B is a cross-sectional view taken along line II-II′ of FIGS. 2A to 2D. In some embodiments, portions of the passivation layer 122, the dielectric structure 114 of the BEOL interconnect structure 110, and the semiconductor substrate 102 are removed from the first side 102a of the semiconductor substrate 102. In some embodiments, the removal of the portions of the passivation layer 122, the dielectric structure 114 of the BEOL interconnect structure 110 and the semiconductor substrate 102 includes a suitable etching. Accordingly, a plurality of first trenches 131 and a plurality of second trenches 133 are formed. As shown in FIGS. 2A to 2D, the first trenches 131 extend in the first direction D1, and the second trenches 133 extend in the second direction D2. Further, the first trenches 131 and the second trenches 133 intersect to form a plurality of intersections 135. In some embodiments, a width Wt1 of each first trench 131 is equal to a width Wt2 of each second trench 133, but the disclosure is not limited thereto. In some embodiments, the width Wt1 of the first trenches 131 is equal to the width W_{SR} of the separation region 106, and the width Wt2 of the second trenches 133 is equal to the width W_{SR} of the separation region 106, but the disclosure is not limited thereto. Further, as shown in the figures, the first trenches 131 and 133 penetrate the passivation layer 122 and the BEOL interconnect structure 110 into the semiconductor substrate 102. A depth of the first trench 131, a depth of the second trench 133 and a depth of the intersections 135 are the same. Further, the depths of the first trenches 131, the second trenches 133 and the intersections 135 are less than a thickness of the semiconductor substrate 102.

As shown in FIGS. 2A to 2D, each of the die regions 104 obtains a first edge E1 and a second edge E2 after the forming of the first trenches 131 and the second trenches 133. The first edge E1 extends in the first direction D1, and the second edge E2 extends in the second direction D2 as seen in the plan view. Further, a protrusion 136 is formed at an intersection of the first edge E1 and the second edge E2 of each die region 104. In some embodiments, a protrusion 136 is formed at every intersection of the first edge E1 and the second edge E2 of each die region 104. The protrusion 136 may have various shapes as seen in the plan view. For example, in some embodiments, the protrusion 136 may have a circular shape, as shown in FIG. 2A. In other embodiments, the protrusion 136 may have a polygon shape as seen in the plan view. For example, the protrusion 136 may have a rectangular shape as seen in the plan view as shown in FIGS. 2B and 2D, or the protrusion 136 may have a triangular shape in the plan view as shown in FIG. 2C.

Each of the protrusions 136 includes materials different from those of other protrusions 136. In some embodiments, the protrusion 136 may include a first portion 136a having a material same as that of the semiconductor substrate 102. In some embodiments, the protrusion 136 may have a second portion 136b over the first portion 136a. The second portion 136b may have a material same as that of the dielectric structure 114 of the BEOL interconnect structure 110. In some embodiments, the protrusion 136 may have a third portion 136c over the second portion 136b. The third portion 136c may have a material same as that of the passivation layer 122. The first portion 136a is coupled to the semiconductor substrate 102, the second portion 136b is coupled to the dielectric structure 114 of the BEOL interconnect structure 110, and the third portion 136c is coupled to the passivation layer 122.

Referring to FIGS. 2A to 3B, due to the protrusions 136 disposed at the intersections of the first edge E1 and the second edge E2 of the die region 104, a width Wi of the intersection 135 is less than or equal to width Wt1 of the first trenches 131, and less than or equal to the width Wt2 of the second trenches 133. In some comparative approaches, when there is no protrusion disposed in the intersections of the first edge E1 and the second edge E2 of the die regions 104, a width Wi of the intersection 135 is greater than the widths Wt1 and Wt2 of the first trenches 131 and the second trenches 133. In such approaches, the width Wi of the intersection 135 may be approximately 1.4 times the widths Wt1 and Wt2 of the first trenches 131 and the second trenches 133. Such width may cause defect in the manufacturing operations, as described below.

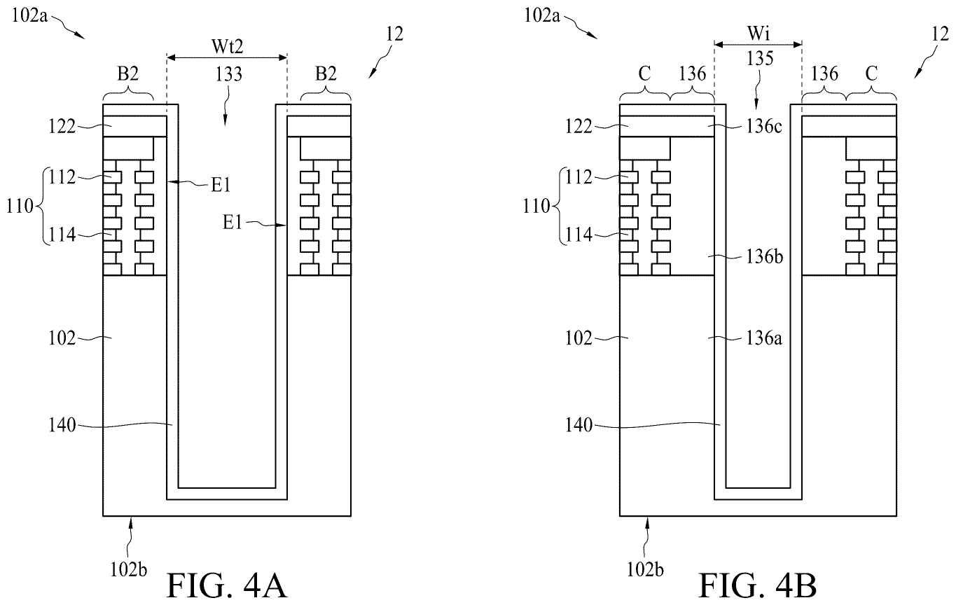

Referring to FIGS. 4A and 4B, in some embodiments, a protection layer 140 is formed over the semiconductor substrate 102 on the first side 102a. In such embodiments, the protection layer 140 covers a bottom and sidewalls of each of the first trenches 131, each of the second trenches 133 and each of the intersections 135. The protection layer 140 includes a material different from that of the dielectric structures 114 of the BEOL interconnect structure 110, and different from that of the passivation layer 122. In some embodiments, the protection layer 140 may include aluminum oxide, but the disclosure is not limited thereto.

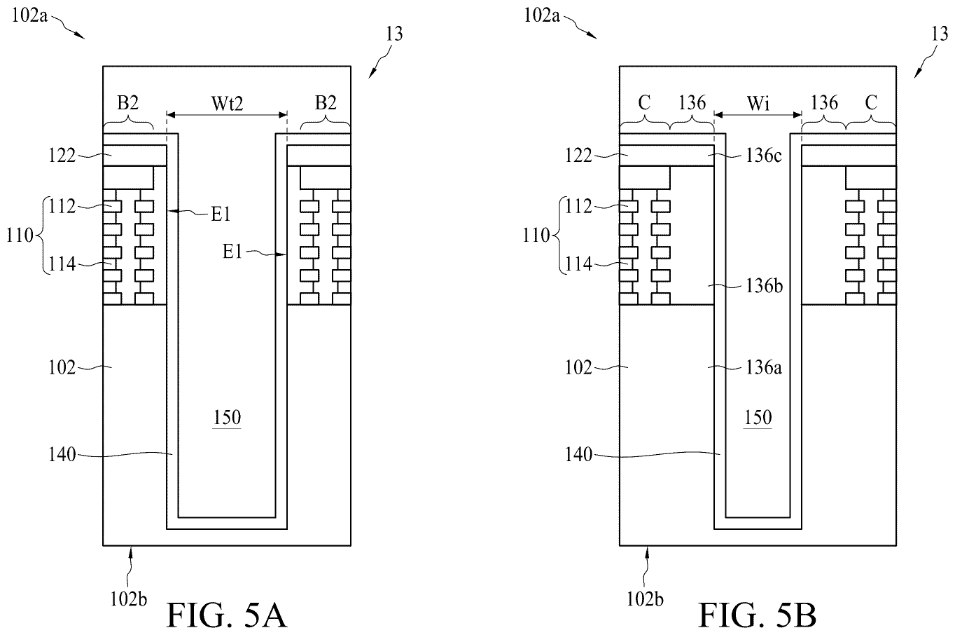

Referring to FIGS. 5A and 5B, in some embodiments, the first trenches 131, the second trenches 133 and the intersections 135 are filled with a dielectric material 150. In some embodiments, the dielectric material 150 may include a material different from that of the protection layer 140. For example, the dielectric material 150 may include silicon oxide, but the disclosure is not limited thereto. In some comparative approaches, when the width Wi of the intersections 135 is greater than the widths Wt1 and Wt2 of the first and second trenches 131 and 133 due to the absence of the protrusion 136, a filling of the trench/gap in the intersections 135 may be incomplete while the trenches 131 and 133 are filled with the dielectric material 150. In such comparative approaches, a gap or a seam may therefore be formed in the intersections 135. Such gap or seam may cause further problem in the manufacturing operations, as detailed below. In contrast with those comparative approaches, due to the protrusions 136, the width Wi of the intersections 135 is less than each of the widths Wt1 and Wt2 of the first and second trenches 131 and 133. As a result, the intersections 135 may be filled with the dielectric material 150 before the first and second trenches 131 and 133 are filled. In other words, the trench/gap-filling result in the intersections 135 is improved by the presence of the protrusions 136.

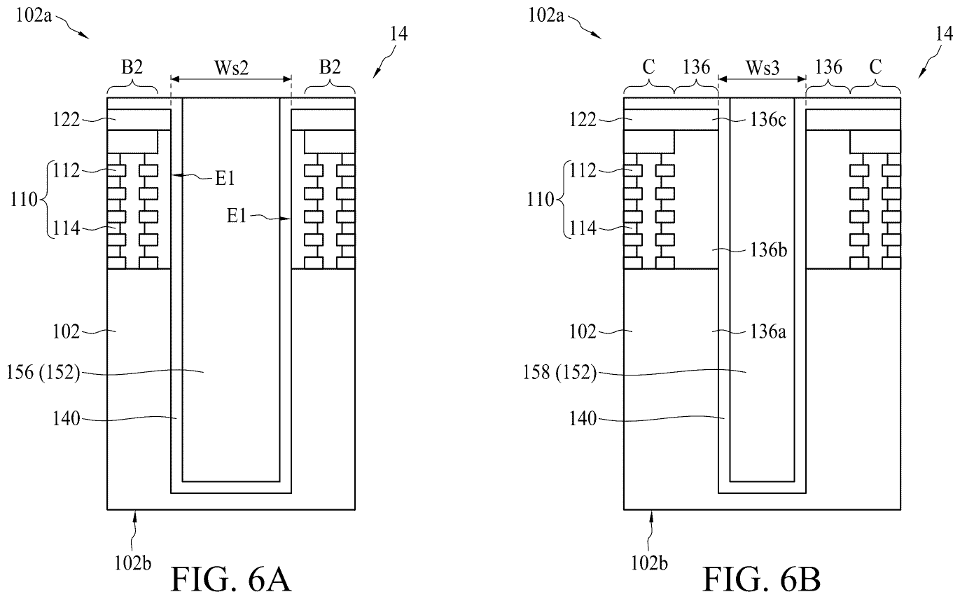

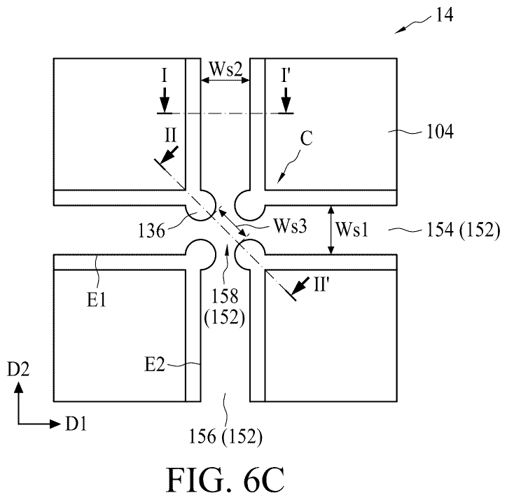

Please refer to FIGS. 6A to 6C, wherein FIG. 6A is a cross-sectional view taken along line I-I′ of FIG. 6C, and FIG. 6B is a cross-sectional view taken along line II-II′ of FIG. 6C. In some embodiments, a planarization is performed on the dielectric material 150 until the protection layer 140 is exposed. The planarization includes a grinding process, a chemical mechanical polishing (CMP) process, an etching process, another applicable process, or a combination thereof. Accordingly, an isolation 152 is formed to separate the die regions 104 from each other. In some embodiments, a top surface of the isolation 152 is exposed through the first side 102a of the semiconductor substrate 102. Further, the top surface of the isolation 152 may be coplanar with (i.e., level with) top surfaces of the protection layer 140 that are exposed after the planarization. Additionally, a depth of the isolation 152 is less than the thickness of the semiconductor substrate 102.

In some comparative approaches as mentioned above, when the protrusion 136 is absent from the intersection 135, a gap or a seam may be formed in the dielectric material 150 due to the incomplete trench/gap-filling. Such gap or seam may impact the planarization result and cause the device to be determined as a defect. Further, etchant may flow into the gap or the seam and cause the dielectric material 150 to deteriorate. In contrast with such comparative approaches, the trench/gap-filling result is improved by the protrusions 136 in the intersections 135, thereby mitigating the abovementioned issues. On the other hand, when the protrusion 136 is absent from the intersection 135, the gap or the seam formed in the dielectric material 150 may reduce the strength of the dielectric material 150, and cracks may occur as a result. In contrast with such comparative approaches, the trench/gap-filling result is improved by the protrusions 136 in the intersections 135, and the abovementioned crack issue is therefore mitigated.

Still referring to FIGS. 6A to 6C, in some embodiments, the isolation 152 includes a first portion 154 extending in the first direction D1 and a second portion 156 extending in the second direction D2, wherein the first portion 154 and the second portion 156 intersect to form an intersection portion 158. A width Ws3 of the intersection portion 158 is less than or equal to each of a width Ws1 of the first portion 154 and a width Ws2 of the second portion 156.

Referring to FIG. 7, in some embodiments, a carrier substrate 160 is temporarily bonded to the first side 102a of the semiconductor substrate 10. In some embodiments, a bonding layer 162 may be provided to bond the semiconductor substrate 102 to the carrier substrate 160. In some embodiments, the carrier substrate 160 is used as a temporary substrate. The temporary substrate provides mechanical and structural support during a subsequent thinning process, which is described in detail below. In some embodiments, the carrier substrate 160 is made of glass material, semiconductor material, ceramic material, polymer material, metal material, another suitable material, or a combination thereof. In some embodiments, the bonding layer 162 includes silicon oxide, but the disclosure is not limited thereto. In some comparative approaches as mentioned above, when the protrusion 136 is absent from the intersection 135, the gap or the seam formed in the dielectric material 150 may negatively affect the bonding between the semiconductor substrate 102 and the bonding layer 162. In contrast with such comparative approaches, because the trench/gap-filling result is improved by the protrusions 136 in the intersections 135, such bonding issue is mitigated.

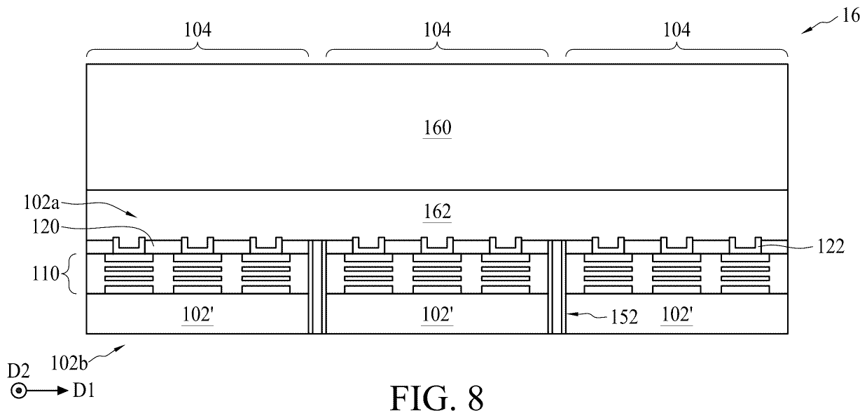

Referring to FIG. 8, the thickness of the semiconductor substrate 102 is reduced in a thinning operation performed on the second side 102b. In some embodiments, the thinning operation is performed on a backside surface of the semiconductor substrate 102 to reduce the thickness of the semiconductor substrate 102. The thinning operation is performed until a bottom surface of the isolation 152 is exposed. As a result, the semiconductor substrate 102 is separated into a plurality of die substrates 102′ separated from each other by the isolation 152. In some embodiments, the thinning operation includes a grinding process, a CMP process, another applicable process, or a combination thereof.

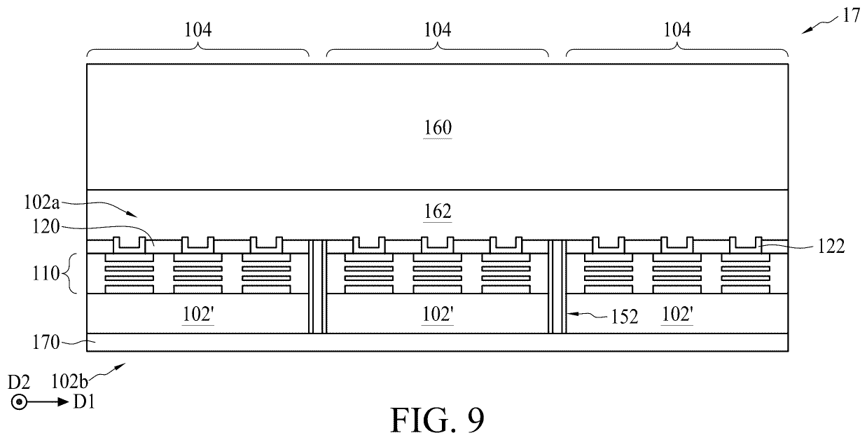

Referring to FIG. 9, a dielectric layer 170 is disposed over the second side 102b of the semiconductor substrate 102 (i.e., the die substrates 102′). The dielectric layer 170 is coupled to the bottom surface of the isolation 152. Further, the dielectric layer 170 includes a material same as that of the isolation 152.

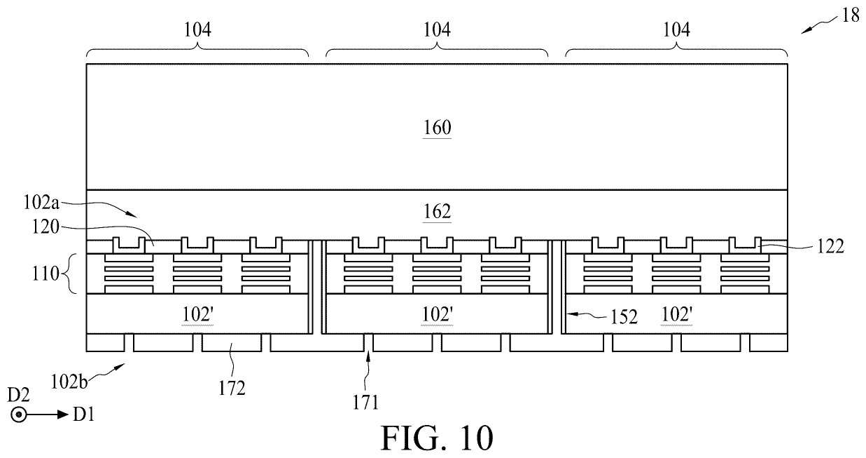

Referring to FIG. 10, in some embodiments, the dielectric layer 170 is patterned using suitable photolithography and etching operations. In such embodiments, a plurality of openings 171 are formed in the dielectric layer 170, thereby forming a patterned dielectric layer 172. In some embodiments, the openings 171 are formed within an area of each of the die substrates 102′, as shown in FIG. 10. Further, in some embodiments, the openings 171 are offset from the isolations 152. Additionally, the backside surface of the semiconductor substrate 102 may be exposed though the openings 171.

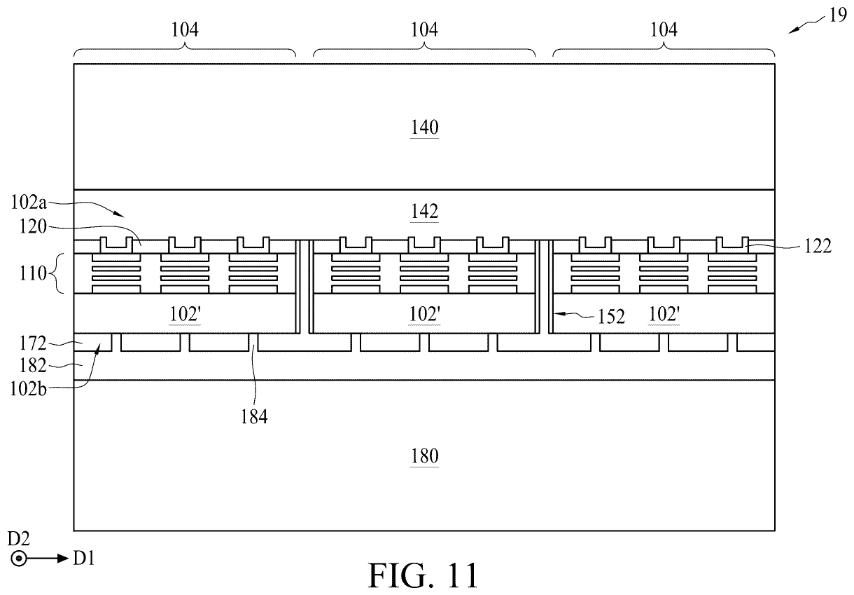

Referring to FIG. 11, in some embodiments, another carrier substrate 180 is attached to the semiconductor substrate 102 (i.e., the die substrates 102′) on the second side 102b. In some embodiments, an adhesive layer 182 may be formed to attach the carrier substrate 180 to the semiconductor substrate 102. In some embodiments, the carrier substrate 180 is used as a temporary substrate. The temporary substrate 180 provides mechanical and structural support during a subsequent thinning process, which is described in detail below. In some embodiments, the carrier substrate 180 is made of glass material, semiconductor material, ceramic material, polymer material, metal material, another suitable material, or a combination thereof. As shown in FIG. 11, the openings 171 are filled with the adhesive layer 182, thereby forming a plurality of adhesive pillars 184. As shown in FIG. 11, the adhesive pillars 184 are formed between the backside surface of the semiconductor substrate 102 and the adhesive layer 182. Further, the adhesive pillars 184 are embedded or surrounded by the patterned dielectric layer 172. In some embodiments, the adhesive layer 182 and the adhesive pillars 184 include benzocyclobutene (BCB), but the disclosure is not limited thereto.

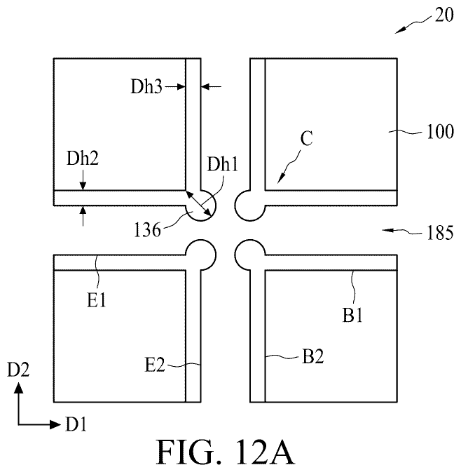

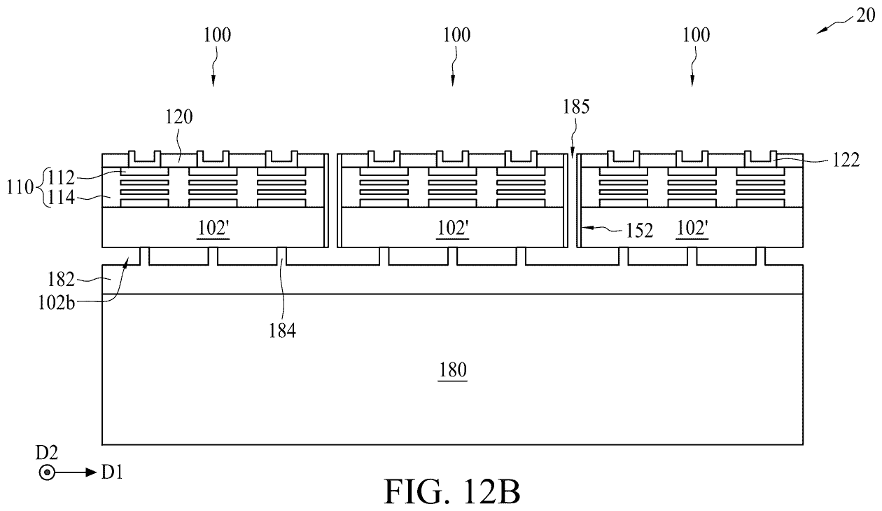

Referring to FIGS. 12A and 12B, in some embodiments, the patterned dielectric layer 172 and the isolation 152 are simultaneously removed. In some embodiments, the removing of the patterned dielectric layer 172 and the isolation 152 can be performed using hydrofluoric acid (HF), but the disclosure is not limited thereto. As shown in FIGS. 12A and 12B, after the removing of the patterned dielectric layer 172 and the isolation 152, a plurality of semiconductor structures 100, such as a plurality of dies 100 or micro-dies 100, are obtained. The semiconductor structures 100 are separated from each other by trenches 185. Additionally, the protection layer 140 that covers sidewalls of each semiconductor structure 100 may be exposed. Further, the semiconductor structures 100 are still attached to the carrier substrate 180 by the adhesive pillars 184, as shown in FIG. 12B.

Still referring to FIGS. 12A and 12B, in some embodiments, each of the semiconductor structures 100 includes a die substrate 102′ and a metallization structure 112 disposed over the die substrate 102′. In some embodiments, the semiconductor structure 100 has a first edge E1 extending in the first direction D1 and a second edge E2 extending in the second direction D2 as seen in the plan view. In some embodiments, the die substrate 102′ has the first edge E1 and the second edge E2. The metallization structure 112 has a first boundary B1 extending in the first direction D1 and a second boundary B2 extending in the second direction D2, and a corner C is formed at an intersection of the first boundary B1 and the second boundary B2 as seen in the plan view. Additionally, the first boundary B1 of the metallization structure 112 corresponds to the first edge E1 of the die substrate 102′, and the second boundary B2 of the metallization structure 112 corresponds to the second edge E2 of the die substrate 102′. Further, the semiconductor structure 100 includes the protrusion 136 disposed at the intersection of the first edge E1 and the second edge E2 of the die substrate 102′. Materials and configurations of the protrusion 136 have been described above, and repeated descriptions are omitted for brevity.

Please refer to FIG. 12A. A first horizontal distance Dh1 is defined between the corner C of the metallization structure 112 and an edge of the protrusion 136 distal to the corner C of the metallization structure 112 as seen in the plan view. A second horizontal distance Dh2 is defined between the first edge E1 of the die substrate 102′ and the first boundary B1 of the metallization structure 112 as seen in the plan view. A third horizontal distance Dh3 is defined between the second edge E2 of the die substrate 102′ and the second boundary B2 of the metallization structure 112 as seen in the plan view. In some embodiments, the second horizontal distance Dh2 is equal to the third horizontal distance Dh3. In some embodiments, the first horizontal distance Dh1 is greater than the second horizontal distance Dh2, and greater than the third horizontal distance Dh3. In some embodiments, the first horizontal distance Dh1 is greater than a value, and the value is obtained according to an equation (1), wherein the equation (1) is:

$${z}^{2} = {x}^{2} + {y}^{2} \qquad ( 1 )$$

wherein x indicates the second horizontal distance Dh2, y indicates the third horizontal distance Dh3, and z indicates the value.

In some comparative approaches, when the protrusion 136 is absent from the semiconductor structure 100, the first edge E1 and the second edge E2 may intersect to form a corner. A distance defined between the corner formed by the first edge E1 and the second edge E2 and the corner C formed by the first boundary B1 and the second boundary B2 may be less than or equal to the abovementioned value “z”. The absence of the protrusion 136 may cause the abovementioned defects and issue.

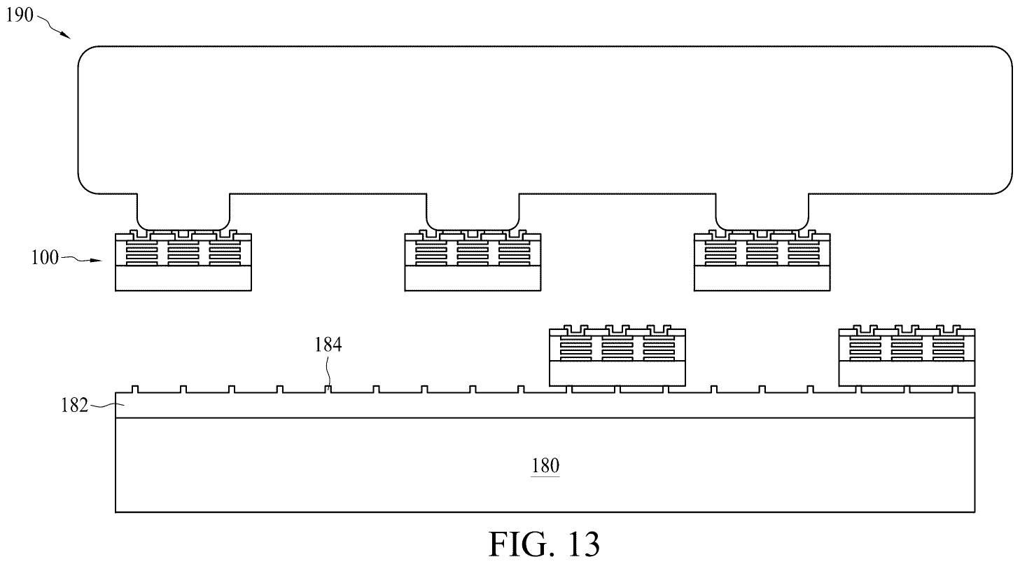

Referring to FIG. 13, in some embodiments, the separated semiconductor structures 100 may be used in a mass transfer. In such embodiments, a pick head 190 may be utilized to pick multiple semiconductor structures 100 at once. In some embodiments, during the pick of the semiconductor structures 100, the multiple semiconductor structures 100 are released from the carrier substrate 180, the adhesive layer 182 and the adhesive pillars 184. In such embodiments, because each of the semiconductor structures 100 is attached to the carrier substrate 180 by the adhesive pillars 184, a contact surface between the adhesive material and the backside surface of each of the semiconductor structures 100 is reduced. Thus, the release of the multiple semiconductor structures 100 can be easily achieved.

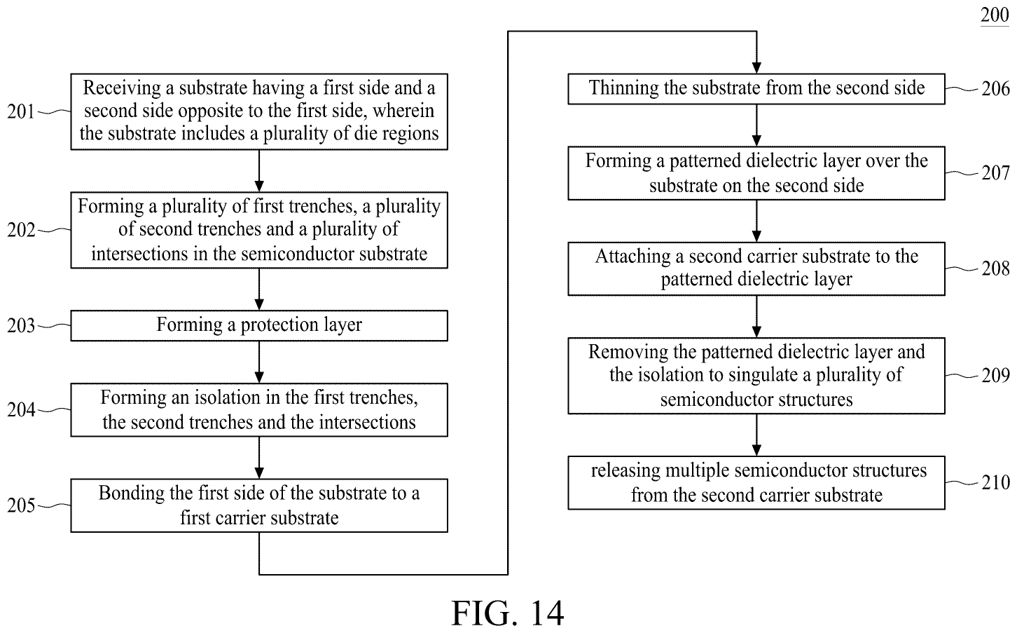

Referring to FIG. 14, a method for forming semiconductor structures 200 is provided. While the disclosed method 200 is illustrated and described herein as a series of acts or operations, it will be appreciated that an order of the illustrated acts or operations is not to be interpreted in a limiting sense. For example, some operations may occur in different orders and/or concurrently with other acts or operations apart from those illustrated and/or described herein. In addition, not all illustrated operations may be required to implement one or more aspects or embodiments of the method disclosed herein. Further, one or more of the operations depicted herein may be carried out in one or more separate operations and/or phases.

In operation 201, a substrate is received. FIG. 1 shows an intermediate semiconductor structure 10 in accordance with some embodiments corresponding to operation 201. In operation 201, the substrate may be a semiconductor substrate 102. The semiconductor substrate 102 has a first side 102a and a second side 102b opposite to the first side 102a. Further, a plurality of die regions 104 are formed in the semiconductor substrate 102. The die regions 104 are separated from each other by a separation region 106. Details of the semiconductor substrate 102 and the die regions 104 may be similar to those described above, and repeated descriptions are omitted for brevity.

In operation 202, a plurality of first trenches 131, a plurality of second trenches 133 and a plurality of intersections 135 are formed in the semiconductor substrate 102. FIGS. 2A to 3B show an intermediate semiconductor structure 11 in accordance with various embodiments corresponding to operation 202. As mentioned above, the first trenches 131 extend in a first direction D1, and the second trenches 133 extend in a second direction D2 perpendicular to the first direction D1. The first trenches 131 and the second trenches 133 intersect to form the intersections 135. In some embodiments, a plurality of protrusions 136 are formed at intersections of a first edge E1 and a second edge E2 of each die region 104. As mentioned above, due to the protrusion 136, a width Wi of the intersection 135 is less than or equal to a width Wt1 of the first trench 131, and less than a width Wt2 of the second trench 133.

In operation 203, a protection layer 140 is formed. FIGS. 4A and 4B show an intermediate semiconductor structure 12 in accordance with some embodiments corresponding to operation 203. As shown in FIGS. 4A and 4B, the protection layer 140 covers a bottom and sidewalls of each first trench 131, a bottom and sidewalls of each second trench 133, and a bottom and sidewalls of each intersection 135. Materials of the protection layer 140 may be similar as those described above, and repeated descriptions of such details are therefore omitted for brevity.

In operation 204, an isolation 152 is formed. FIGS. 5A to 6C show intermediate semiconductor structures 13 and 14 in accordance with some embodiments corresponding to operation 204. As shown in FIGS. 5A and 5B, a dielectric material 150 is formed to fill the first trenches 131, the second trenches 133 and the intersections 135. As mentioned above, due to the protrusions 136, a trench/gap-filling result in the intersection 135 is improved. As shown in FIGS. 6A to 6C, a planarization operation is performed on the first side 102a of the semiconductor substrate 102 in order to remove a portion of the dielectric material 150 and to form the isolation 152 separating the die regions 104 from each other. Further, a top surface of the isolation 152 is exposed on the first side 102a of the semiconductor substrate 102. As mentioned above, due to the protrusion 136, the trench/gap-filling result is improved, thereby mitigating a defect that may be caused during the planarization. As shown in FIG. 6C, the isolation 152 includes a first portion 154 extending in the first direction D1, a second portion 156 extending in the second direction D2, and an intersection portion 158 disposed where the first portion 154 and the second portion 156 intersect. Due to the protrusion 136, a width Ws3 of the intersection portion 158 is less than a width Ws1 of the first portion 154, and less than a width Ws2 of the second portion 156.

In operation 205, the semiconductor substrate 102 is bonded to a first carrier substrate 160. FIG. 7 shows an intermediate semiconductor structure 15 in accordance with some embodiments corresponding to operation 205. In some embodiments, the semiconductor substrate 102 is bonded to the first carrier substrate 160 by a bonding layer 162. Materials of the bonding layer 162 may be similar to those described above, such details are therefore omitted for brevity. As mentioned above, due to the protrusion 136, the trench/gap-filling result is improved, therefore the bonding between the semiconductor substrate 102 and the bonding layer 162 may be improved.

In operation 206, a thickness of the semiconductor substrate 102 is reduced on the second side 102b. FIG. 8 shows an intermediate semiconductor structure 16 in accordance with some embodiments corresponding to operation 206. In some embodiments, a bottom of the isolation 152 is exposed through the second side 102b after the thinning of the semiconductor substrate 102. In some embodiments, the semiconductor substrate 102 may be referred to as a plurality of die substrates 102′ separated from each other by the isolation 152. Additionally, the protection layer 140 is left to cover sidewalls of each die region 104.

In operation 207, a patterned dielectric layer 172 is formed over the second side 102b of the semiconductor substrate 102. FIGS. 9 and 10 show intermediate semiconductor structures 17 and 18 in accordance with some embodiments corresponding to operation 207. As shown in FIG. 9, in some embodiments, a dielectric layer 170 having a material same as that of the isolation 152 is formed over the backside surface of the semiconductor substrate 102. The dielectric layer 170 is coupled to the isolation 152. As shown in FIG. 10, the dielectric layer 170 is patterned to form a plurality of openings 171, thereby forming the patterned dielectric layer 172. In some embodiments, the backside surface of the semiconductor substrate 102 is exposed through the openings 171.

In operation 208, a second carrier substrate 180 is attached to the second side 102b of the semiconductor substrate 102. FIG. 11 shows an intermediate semiconductor structure 19 in accordance with some embodiments corresponding to operation 208. In some embodiments, the attaching of the second carrier substrate 180 to the semiconductor substrate 102 including using an adhesive layer 182. The openings 171 may be filled with the adhesive layer 182 to form a plurality of adhesive pillars 184 in contact with the backside surface of each die substrate 102′. Materials of the second carrier substrate 180 and materials of the adhesive layer 182 and the adhesive pillars 184 may be similar to those described above, and repeated descriptions are omitted for brevity.

In operation 209, the isolation 152 and the patterned dielectric layer 172 are removed to singulate a plurality of semiconductor structures 100. FIGS. 12A and 12B show an intermediate semiconductor component 20 in accordance with some embodiments corresponding to operation 209. In some embodiments, the semiconductor structures 100 are separated from each other by trenches 185, but are still attached to the second carrier substrate 180 by the adhesive pillars 184.

In operation 210, multiple semiconductor structures 100 are released from the second carrier substrate 180. As shown in FIG. 13, a pick head 190 may be utilized to pick multiple semiconductor structures 100 from the second carrier substrate 180. As mentioned above, because each of the semiconductor structures 100 is attached to the second carrier substrate 180 by the adhesive pillars 184, it is easy to pick multiple semiconductor structures 100 at once. Accordingly, the method for forming the semiconductor structure 200 can be integrated in a mass transfer scheme. For example, the method can be integrated in a mass transfer scheme for micro dies, such as micro-LED dies.

Accordingly, the present disclosure provides a semiconductor structure including a die (or a package) having at least a protrusion disposed over a corner as seen in a plan view. Such protrusion helps to mitigate a defect issue found in manufacturing operations by reducing a width of an intersection, thus improving a filling of a trench or gap and mitigating defect issues in the manufacturing operations.

In some embodiments, a semiconductor structure is provided. The semiconductor structure includes a die substrate, a metallization structure disposed over the die substrate, and a protrusion. The die substrate has a first edge extending in a first direction and a second edge extending in a second direction different from the first direction as seen in a plan view. The metallization structure has a first boundary extending in the first direction and a second boundary extending in the second direction, and a corner is formed at an intersection of the first boundary and the second boundary. The protrusion is disposed at an intersection of the first edge and the second edge of the die substrate. A first horizontal distance is defined between the corner of the metallization structure and an edge of the protrusion distal to the corner of the metallization structure as seen in the plan view, a second horizontal distance is defined between the first edge of the die substrate and the first boundary of the metallization structure as seen in the plan view, and a third horizontal distance is defined between the second edge of the die substrate and the second boundary of the metallization structure as seen in the plan view.

In some embodiments, a method for forming semiconductor structures is provided. The method includes following operations. A substrate is received. The substrate has a first side and a second side opposite to the first side. The substrate has a plurality of die regions. A plurality of first trenches and a plurality of second trenches are formed to separate the die regions from each other. The plurality of first trenches extend in a first direction, and the plurality of second trenches extend in a second direction different from the first direction. The first trenches and the second trenches intersect to form a plurality of intersections. A width of the intersection is less than or equal to each of a width of the first trench and a width of the second trench. A protection layer is formed over a bottom and sidewalls of each first trench, each second trench and each intersection. An isolation separating the plurality of die regions from each other is formed in the plurality of first trenches, the plurality of second trenches and the plurality of intersections.

In some embodiments, a method for forming semiconductor structures is provided. The method includes following operations. A substrate is received. The substrate has a first side and a second side opposite to the first side. The substrate includes a plurality of die regions separated from each other by an isolation. A top surface of the isolation is exposed through the first side of the substrate. The isolation includes a first portion extending in a first direction and a second portion extending in a second direction different from the first direction. The first portion and the second portion intersect to form an intersection portion. A width of the intersection portion is less than or equal to each of a width of the first portion and a width of the second portion. The first side of the substrate is bonded to a first carrier substrate. The substrate is thinned on the second side. A patterned dielectric layer is formed over the substrate on the second side. A second carrier substrate is attached to the patterned dielectric layer. The patterned dielectric layer and the isolation are removed to singulate a plurality of semiconductor structures over the second carrier substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure comprising:
a die substrate having a first edge extending in a first direction and a second edge extending in a second direction different from the first direction as seen in a plan view;
a metallization structure disposed over the die substrate, wherein the metallization structure has a first boundary extending in the first direction, a second boundary extending in the second direction, and a corner formed at an intersection of the first boundary and the second boundary as seen in the plan view; and
a protrusion disposed at an intersection of the first edge and the second edge of the die substrate.

2. The semiconductor structure of claim 1, wherein a first horizontal distance is defined between the corner of the metallization structure and an edge of the protrusion distal to the corner of the metallization structure as seen in the plan view, a second horizontal distance is defined between the first edge of the die substrate and the first boundary of the metallization structure as seen in the plan view, and a third horizontal distance is defined between the second edge of the die substrate and the second boundary of the metallization structure as seen in the plan view,
wherein the first horizontal distance is greater than a value, and the value is obtained according to an equation (1),
wherein the equation (1) is:
$${z}^{2} = {x}^{2} + {y}^{2} \qquad ( 1 )$$
wherein x indicates the second horizontal distance, y indicates the third horizontal distance, and z indicates the value.

3. The semiconductor structure of claim 1, wherein the protrusion comprises a first material and a second material disposed over the first material.

4. The semiconductor structure of claim 3, wherein the first material of the protrusion and a material of the die substrate comprise a same material.

5. The semiconductor structure of claim 3, further comprising a dielectric structure disposed over the die substrate, wherein the metallization structure is disposed in the dielectric structure, and the second material of the protrusion and a material of the dielectric structure comprise same materials.

6. A method of forming a semiconductor structure, comprising:
receiving a substrate having a first side and a second side opposite to the first side, wherein the substrate comprises a plurality of die regions;
forming a plurality of first trenches and a plurality of second trenches separating the die regions from each other, wherein the plurality of first trenches extend in a first direction, the plurality of second trenches extend in a second direction different from the first direction, the first trenches and the second trenches intersect to form a plurality of intersections, and a width of the intersection is less than or equal to each of a width of the first trench and a width of the second trench;
forming a protection layer over a bottom and sidewalls of each first trench, each second trench and each intersection; and
forming an isolation separating the plurality of die regions from each other in the plurality of first trenches, the plurality of second trenches and the plurality of intersections.

7. The method of claim 6, wherein a depth of the first trench, a depth of the second trench and a depth of the intersection are each less than a thickness of the substrate.

8. The method of claim 6, wherein the protection layer and the isolation comprise different materials.

9. The method of claim 6, further comprising:
thinning the substrate on the second side of the substrate;
forming a dielectric layer over the substrate on the second side;
attaching a carrier substrate to the dielectric layer; and
removing the isolation to singulate a plurality of dies separated from each other.

10. The method of claim 9, wherein the dielectric layer and the isolation comprise a same material.

11. The method of claim 9, wherein a bottom of the isolation is exposed after the thinning of the substrate.

12. The method of claim 9, wherein the protection layer is exposed over sidewalls of each die.

13. A method of forming semiconductor structures, comprising:
receiving a substrate having a first side and a second side opposite to the first side, wherein the substrate comprises a plurality of die regions separated from each other by an isolation, and a top surface of the isolation is exposed through the first side of the substrate;
bonding the first side of the substrate to a first carrier substrate;
thinning the substrate on the second side of the substrate;
forming a patterned dielectric layer over the substrate on the second side;
attaching a second carrier substrate to the patterned dielectric layer; and
removing the patterned dielectric layer and the isolation to singulate a plurality of semiconductor structures over second carrier substrate,
wherein the isolation comprises a first portion extending in a first direction and a second portion extending in a second direction different from the first direction, the first portion and the second portion intersect to form an intersection portion, and a width of the intersection portion is less than or equal to each of a width of the first portion and a width of the second portion.

14. The method of claim 13, wherein a depth of the isolation is less than a thickness of the substrate.

15. The method of claim 13, wherein a bottom surface of the isolation is exposed through the second side of the substrate after the thinning of the substrate.

16. The method of claim 13, wherein the patterned dielectric layer and the isolation comprise a same material.

17. The method of claim 13, wherein the forming of the patterned dielectric layer further comprises:
forming a dielectric layer over the substrate on the second side; and
forming a plurality of openings in the dielectric layer.

18. The method of claim 17, wherein the attaching of the second carrier substrate to the patterned dielectric layer further comprises:
forming an adhesive layer over the patterned dielectric layer, wherein the plurality of openings are filled with the adhesive layer; and
disposing the second carrier substrate over the adhesive layer.

19. The method of claim 13, further comprising removing the first carrier substrate.

20. The method of claim 19, further comprising releasing multiple semiconductor structures from the second carrier substrate.
